(19) United States
(12) Patent Application Publication
(10) Pub. No.: US 2006/0049439 A1
(43) Pub. Date: Mar. 9, 2006

(54) Image device and method of fabricating the same

(75) Inventors: Hyeok-Sang Oh, Suwon-si (KR); Ju-Hyuck Chung, Suwon-si (KR); Kwang-Myeon Park, Yongin-si (KR); In-Soo Cho, Hwaseong-si (KR); Seong-Il Kim, Yongin-si (KR)

Correspondence Address: F. CHAU & ASSOCIATES, LLC, 130 WOODBURY ROAD, WOODBURY, NY, 11797, US

(73) Assignee: Samsung Electronics Co., LTD, Suwon-si (KR)

(21) Appl. No.: 11/220,295

(22) Filed: Sep. 6, 2005

(30) Foreign Application Priority Data
Sep. 8, 2004 (KR) 10-2004-0071761

(51) Int. Cl. H01L 31/062

(52) U.S. Cl. 257/292

(57) ABSTRACT

An image device includes a substrate in which a light receiving element is formed, an interlayer dielectric structure which is formed on the substrate and has a cavity over the light receiving element, a transparent dielectric layer which fills the cavity and has a lens-shaped portion protruding beyond an upper portion of the interlayer dielectric structure, and a color filter which is formed on the transparent dielectric layer.

### CROSS-REFERENCE TO RELATED APPLICATIONS

This application claims priority to Korean Patent Application No. 10-2004-0071761 filed on Sep. 8, 2004 in the Korean Intellectual Property Office, the disclosure of which is incorporated herein by reference in its entirety.

### BACKGROUND OF THE INVENTION

1. Technical Field

The present disclosure relates to an image device and a method of fabricating the same, and more particularly, to a complementary metal oxide semiconductor (CMOS) image device fabricated using a copper damascene process and a method of fabricating the same.

2. Discussion of Related Art

A CMOS image sensor includes a light sensing part for sensing light and a logic circuit part for converting sensed light into an electronic signal and converting the electronic signal into data. To increase light sensitivity, an effort has been made to increase a ratio of an area occupied by the light sensing part in the CMOS image sensor.

With progress in producing high-speed and highly-integrated logic devices, techniques for fabricating miniaturized transistors have been developed. As integration of transistors is increased, interconnections become smaller. As a result, interconnection delay becomes more serious, thereby impeding performance of high-speed logic devices.

For an interconnection material, copper has been used. The copper has a lower resistance and higher electromigration (EM) tolerance than a conventional material such as an aluminum alloy, which has been used for interconnecting large scale integrated (LSI) semiconductor devices. However, copper cannot be easily etched, and is prone to oxidation. Thus, a dual damascene process has been performed to form a copper interconnection.

When a CMOS image device is fabricated using a copper damascene process, light transmittance is reduced in a light sensing element such as a photodiode. The reduction in light transmittance occurs because interlayer dielectric layers and etch stop layers having different reflectances and index of refractions are alternately stacked so that irregular reflection and refraction of light occur at interfaces between the interlayer dielectric layers and the etch stop layers. The interlayer dielectric layers and the etch stop layers comprise, for example, silicon nitride (SiN).

Accordingly, the development of an image device with improved light transmittance while using the copper damascene process is needed.

### SUMMARY OF THE INVENTION

According to an embodiment of the present invention, an image device with improved light transmittance includes an interconnection pattern fabricated using a copper damascene process.

According to an embodiment of the present invention, an image device prevents scattering and irregular reflection of light. Thus light sensitivity can be improved.

According to an embodiment of the present invention, a method of fabricating an image device is disclosed. The method can simultaneously form a micro lens for improving light sensitivity when forming a dielectric layer comprising a transparent material for improving light transmittance.

According to an embodiment of the present invention, a method of fabricating an image device includes a simplified fabrication process.

According to an embodiment of the present invention, an image device includes a substrate in which a light receiving element is formed, an interlayer dielectric structure which is formed on the substrate and has a cavity over the light receiving element, a transparent dielectric layer which fills the cavity and has a portion having a lens shape protruding beyond an upper portion of the interlayer dielectric structure, and a color filter which is formed on the transparent dielectric layer.

The upper portion of the transparent dielectric layer may be formed into either a convex lens shape or a concave lens shape.

The interlayer dielectric structure may include copper contacts and copper interconnects, and a diffusion preventing layer for preventing diffusion of the copper contacts and copper interconnects. The transparent dielectric layer may comprise a spin-on-dielectric material.

According to an embodiment of the present invention, a method of fabricating an image device includes forming a semiconductor device for driving a light receiving element, and an interlayer dielectric structure including copper contacts electrically connected to the semiconductor device and copper interconnects, on a substrate in which the light receiving element is formed, removing a portion of the interlayer dielectric structure located on an upper portion of the light receiving element to form a cavity, forming a transparent dielectric layer having a thickness to fill the cavity, forming an upper portion of the transparent dielectric layer over the light receiving element into a convex lens shape to form a first micro lens, and forming a color filter on the first micro lens.

The fabrication method of the image device may further comprise forming a second micro lens on the color filter.

Before forming the color filter, the fabrication method may further include forming a protection layer on the first micro lens and planarizing the protection layer.

The step of forming the first micro lens may include planarizing the transparent dielectric layer, removing the transparent dielectric layer except for the transparent dielectric layer located on the light receiving element, and performing an etch-back process to form the upper portion of the transparent dielectric layer located on the light receiving element into a convex lens shape.

The etch-back process may be performed until an edge portion of the upper portion of the transparent dielectric layer is first removed until the upper portion of the transparent dielectric layer is formed into the concave lens type.

The step of forming the first micro lens may include planarizing the transparent dielectric layer, removing the transparent dielectric layer on the interlayer dielectric structure except for the transparent dielectric layer located on the upper portion of the light receiving element, and performing a thermal process to reflow the upper portion of the transparent dielectric layer located on the light receiving element, thereby forming the upper portion of the transparent dielectric layer into a concave lens type.

According to an embodiment of the present invention, a method of fabricating an image device includes forming a semiconductor device for driving a light receiving element, and an interlayer dielectric structure including copper contacts electrically connected to the semiconductor device and/or copper interconnects, on a substrate in which the light receiving element is formed, removing a portion of the interlayer dielectric structure located on the light receiving element to form a cavity, forming a transparent dielectric layer having a thickness to fill the cavity, the transparent dielectric layer being formed to a predetermined thickness such that an upper portion of the cavity has a concave profile, removing the transparent dielectric layer except for the transparent dielectric layer disposed over the light receiving element to form a first micro lens in which the upper portion of the transparent dielectric layer is formed into a concave lens shape, forming a color filter on the first micro lens, and forming a second micro lens on the color filter.

The second micro lens is preferably a convex micro lens.

The copper contacts and the copper interconnects are formed using a single or dual damascene process.

### BRIEF DESCRIPTION OF THE DRAWINGS

Preferred embodiments of the present disclosure can be understood in more detail from the following descriptions taken in conjunction with drawings in which:

FIG. 1 is a cross-sectional view of an image device according to an embodiment of the present invention;

FIGS. 2A through 2M are cross-sectional views illustrating a method of fabricating the image device shown in FIG. 1 according to an embodiment of the present invention;

FIG. 3 is a cross-sectional view of an image device according to an embodiment of the present invention;

FIGS. 4A through 4C are cross-sectional views illustrating a method of fabricating an image device shown in FIG. 3 according to an embodiment of the present invention; and

FIG. 5 is a cross-sectional view of an image device according to an embodiment of the present invention.

### DETAILED DESCRIPTION OF THE PREFERRED EMBODIMENTS

Preferred embodiments of the present invention will be described below in more detail with reference to the accompanying drawings. The present invention may, however, be embodied in many different forms and should not be construed as being limited to the embodiments set forth herein. Like reference numerals refer to like elements throughout the specification.

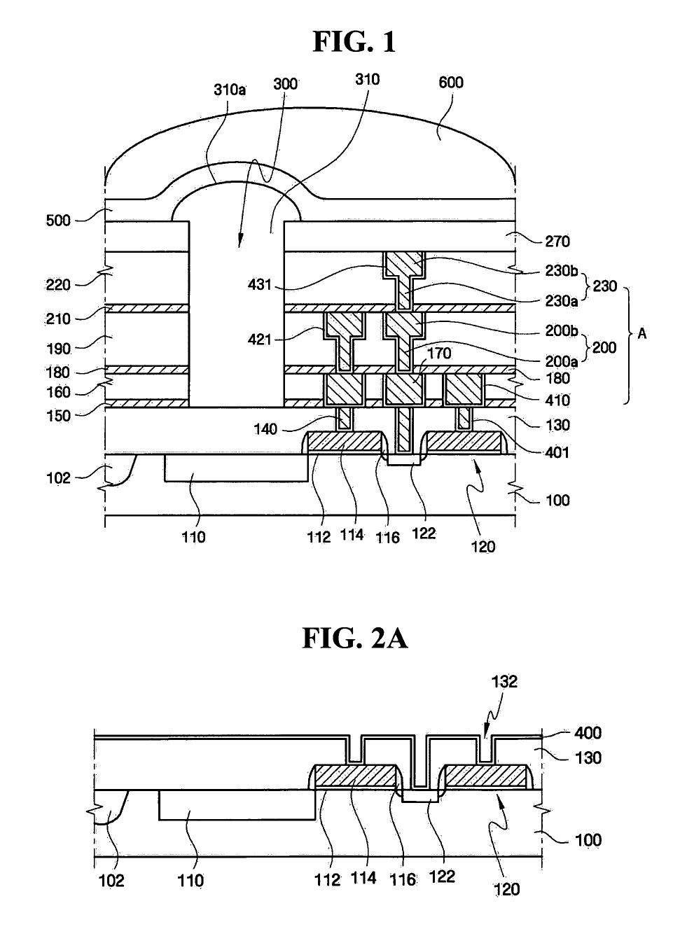

An image device according to an embodiment of the present invention will be described with reference to FIG. 1. FIG. 1 is a cross-sectional view of an image device according to an embodiment of the present invention.

As shown in FIG. 1, the image device according to an embodiment of the present invention includes a semiconductor substrate 100 having a light receiving element such as a photodiode 10 on a surface of an active region defined by a field oxide layer 102. Transistors 120, which are switching devices, are formed on the semiconductor substrate 100. The transistors 120 include a gate electrode 114, a gate dielectric layer 112 interposed between the semiconductor substrate 100 and the gate electrode 114, and a source/drain region 122 formed between the gate electrodes 114. Spacers 116 are formed on sidewalls of the gate electrode 114.

A lower dielectric layer 130 comprising a transparent material such as silicon oxide is formed on the semiconductor substrate 100 on which the transistor 120 is formed. A lower contact 140 which is electrically connected to the source/drain region 122 and the gate electrode 114 of the transistor 120 is formed in a predetermined region of the lower dielectric layer 130. The lower contact 140 can comprise a metal such as copper, titanium or tungsten. A first barrier metal layer 401 is formed between the lower contact 140 and the lower dielectric layer 130 to prevent a metal comprising the lower contact 140 from diffusing into the lower dielectric layer 130.

An interlayer dielectric structure A is formed on the lower dielectric layer 130. The interlayer dielectric structure A includes a cavity 300 formed by removing elements located on an upper portion of the photo diode 110, multi-layered etch stop layers 150, 180 and 210, multi-layered interlayer dielectric layers 160, 190 and 220, and multi-layered metal interconnections 170, 200 and 230.

The etch stop layers 150, 180 and 210 functioning as internal diffusion preventing and etch stop layers, and the interlayer dielectric layers 160, 190 and 220 are alternately stacked in the interlayer dielectric structure A. The etch stop layers 150, 180 and 210 and the interlayer dielectric layers 160, 190 and 220 comprise different materials having different characteristics with respect to light. The cavity 300, formed by removing portions of the etch stop layers 150, 180 and 210 and the interlayer dielectric layers 160, 190 and 220, located on the upper portion of the photodiode 110, is included in the interlayer dielectric structure A so that external incident light can reach the photodiode 110.

The interlayer dielectric structure A includes the first etch stop layer 150 which is partially formed on the lower dielectric layer 130 which includes the lower contact 140. That is, the first etch stop layer 150 is formed to cover the lower dielectric layer 130 except for a portion corresponding to the cavity 300, which is formed on the upper portion of the photodiode 110. The first etch stop layer 150 prevents the lower dielectric layer 130 from being etched when forming trenches for a lower copper interconnection 170, which will be described below. The first etch stop layer 150 can comprise a material having a large etch selectivity with respect to the lower dielectric layer 130, for example, silicon nitride (SiN) or a SiN based material. The second and third etch stop layers 180 and 210, which will be described, may comprise the same material as the first etch stop layer 150.

The first interlayer dielectric layer 160 is formed on the first etch stop layer 150. The first interlayer dielectric layer 160 may comprise a transparent insulating material. Alternatively, an opaque insulating material may be used. The first interlayer dielectric layer 160 may comprise undoped silicate glass (USG), phospho silicate glass (PSG), borophospho silicate glass (BPSG), hydrogen silsesquioxane (HSQ), fluoro silicate glass (FSG) or an oxide layer. The second interlayer dielectric layer 190 and the upper interlayer dielectric layer 220 may comprise the same material as the first interlayer dielectric layer 160.

The lower copper interconnection 170 is a conductive line comprising copper. The lower copper interconnection 170 is electrically connected to the lower contact 140 and is formed in the first interlayer dielectric layer 160. A second barrier metal layer 410 is formed on sidewalls and a bottom surface of the lower copper interconnection 170 to prevent copper comprising the lower copper interconnection 170 from diffusing into the first interlayer dielectric layer 160.

The second etch stop layer 180 is formed on the first interlayer dielectric layer 160 including the lower copper interconnection 170. The second interlayer dielectric layer 190 is formed on the second etch stop layer 180. A first interconnection 200 is formed in the second interlayer dielectric layer 190. Each first interconnection 200 includes a first copper contact 200a electrically connected to a lower copper interconnection 170 and a first copper interconnect 200b. The first copper interconnects 200b connect the first copper contacts 200a to one another and are conductive lines for transmitting a signal. A third barrier metal layer 421 is formed between the first interconnection 200 and the second interlayer dielectric layer 190 to prevent a material comprising the first interconnection 200 from diffusing into the second interlayer dielectric layer 190.

The third etch stop layer 210 and the upper interlayer dielectric layer 220 are formed on the second interlayer dielectric layer 190. A second interconnection 230 is formed in the upper interlayer dielectric layer 220. Each second interconnection 230 includes a second copper contact 230a electrically connected to the first interconnection 200 and a second copper interconnect 230b. The second copper interconnects 230b connect the second copper contacts 230a to each other and are conductive lines for transmitting a signal. A fourth barrier metal layer 431 is formed between the second interconnection 230 and the upper interlayer dielectric layer 220 to prevent a material comprising the second interconnection 230 from diffusing into the upper interlayer dielectric layer 220.

The cavity 300 is formed on the lower dielectric layer 130 located on the photodiode 110 through the first etch stop layer 150, the first interlayer dielectric layer 160, the second etch stop layer 180, the second interlayer dielectric layer 190, the third etch stop layer 210 and the upper interlayer dielectric layer 220.

A protection layer 270 which protects the multi-layered interconnects 170, 200 and 230 while exposing the cavity 300 may be formed on the upper interlayer dielectric layer 220.

A spin-on dielectric layer 310 comprising, for example, resin that is transmissible with respect to light detected by the image device is formed within the cavity 300. The spin-on dielectric layer 310 completely fills the cavity 300 and its upper portion has a profile of a convex lens.

A first micro lens 310a has a structure formed by the profile of the convex lens of the upper portion of the spin-on dielectric layer 310. The first micro lens 310a focuses light on the surface of the photo diode 110, thereby preventing scattering and irregular reflection of the light.

A color filter 500 is formed on the spin-on dielectric layer 310 and the protection layer 270. A second micro lens 600 having a convex lens shape can be formed on the color filter 500. The second micro lens 600 can increase a function of the first micro lens 310a. Thus, if the first micro lens 310a sufficiently performs a focusing function, the second micro lens 600 may not be formed.

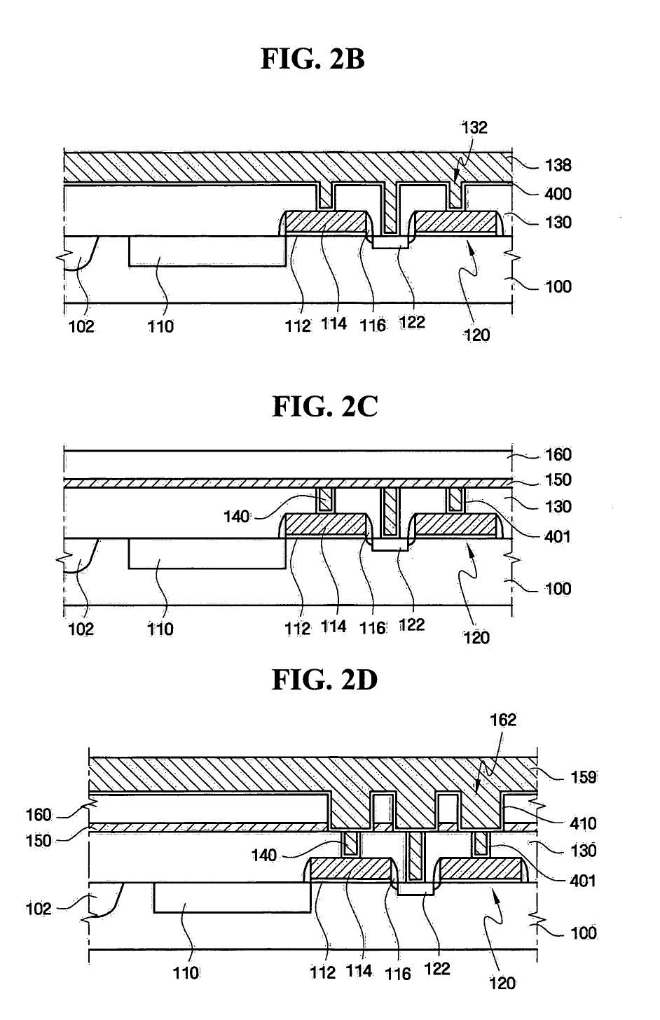

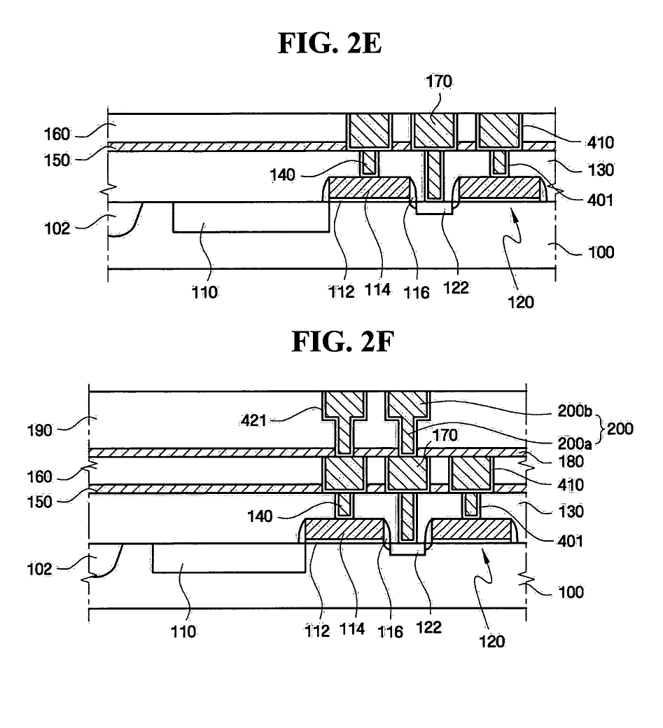

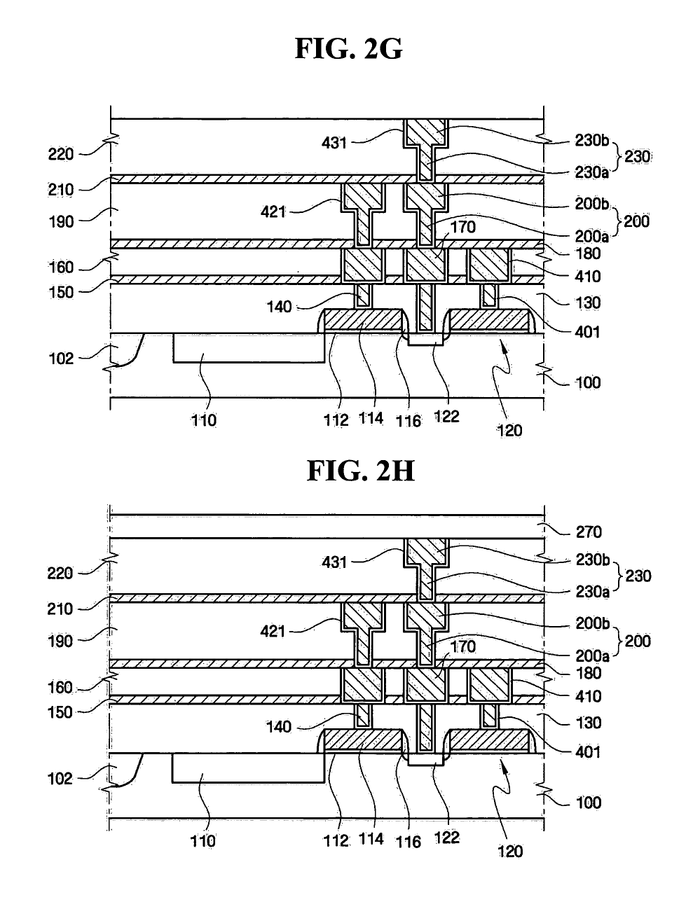

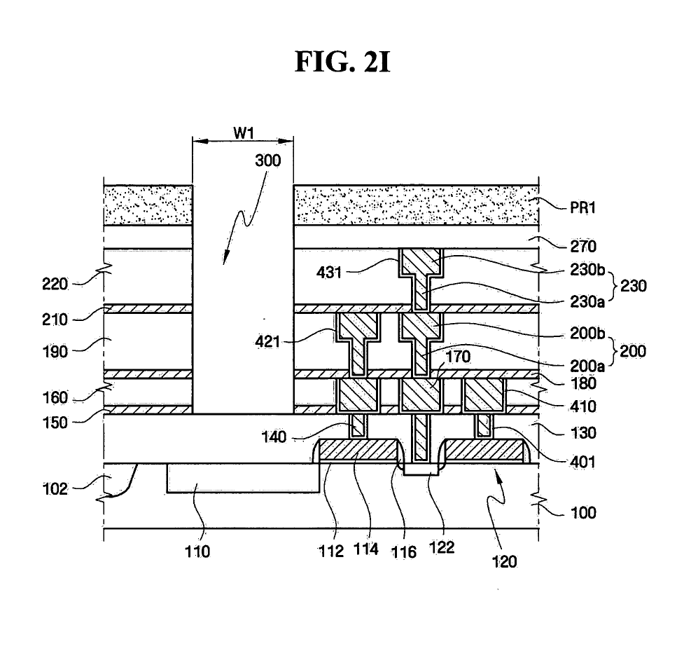

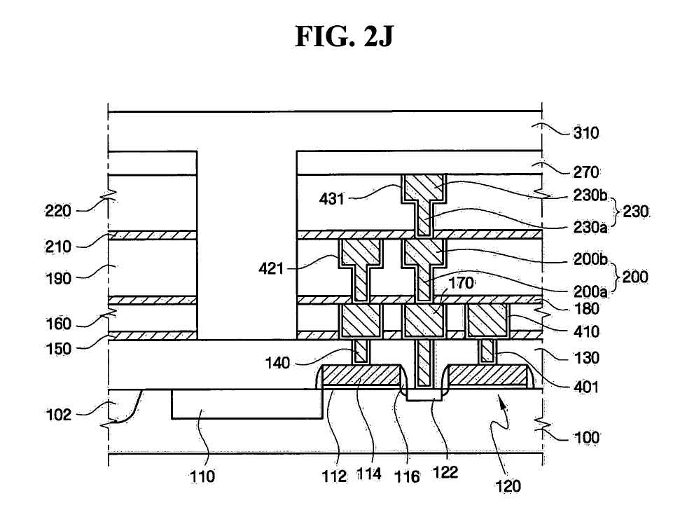

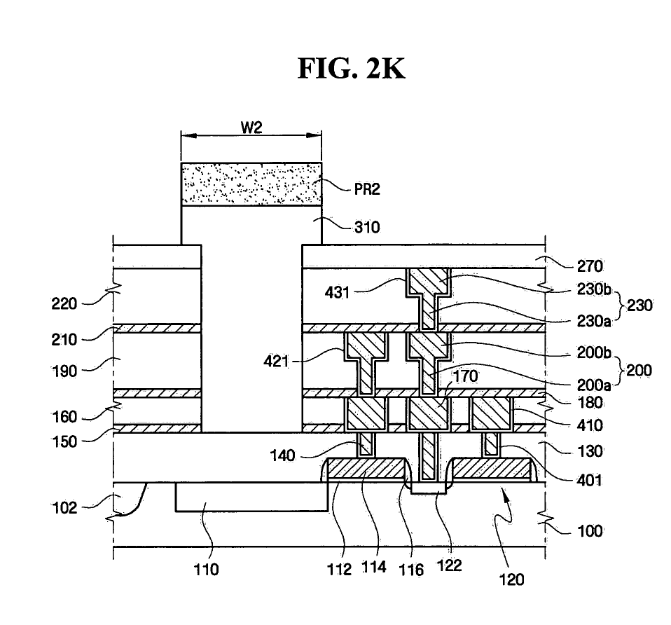

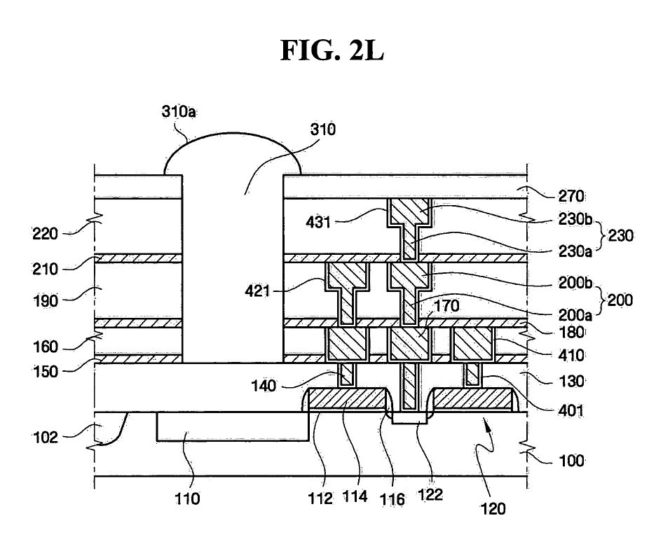

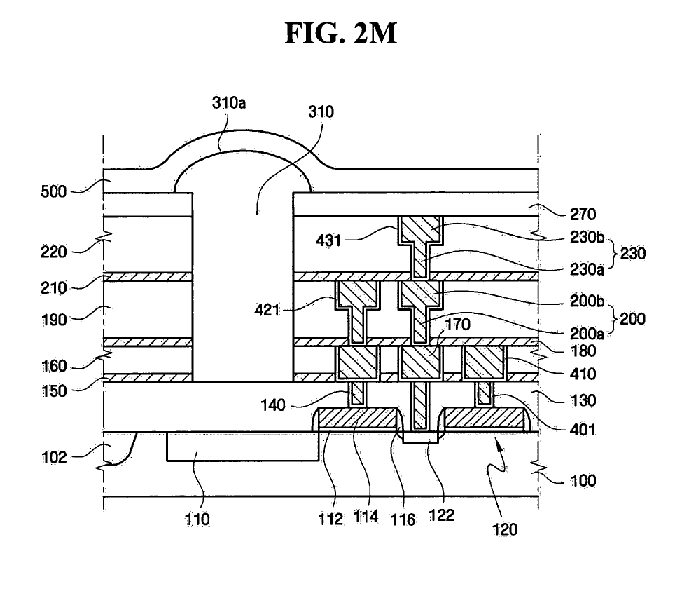

A method of fabricating the image device according to an embodiment of the present invention will be described with reference to FIGS. 2A through 2M and FIG. 1. FIGS. 2A through 2M are cross-sectional views illustrating a method of fabricating the image device according to an embodiment of the present invention.

As shown in FIG. 2A, the field oxide layer 102 is formed on an upper portion of the semiconductor substrate 100, thereby defining an active region. A light receiving element such as the photodiode 110 is formed on the surface of the active region. The transistors 120 which are switching devices of the photodiode 110 are formed on the semiconductor substrate 100 to connect to the photodiode 110.

Each of the transistors 120 includes the gate electrode 114, the gate dielectric layer 112 interposed between the semiconductor substrate 100 and the gate electrode 114, and the source/drain region 122 which is an impurity region formed in the semiconductor substrate 100 between the gate electrodes 114. The spacers 116 are formed on sidewalls of the gate electrode 114.

Next, the lower dielectric layer 130 is formed to cover the semiconductor substrate 100 on which the transistors 120 are formed. The lower dielectric layer 130 comprises a transparent material such as, for example, a silicon oxide based material.

Next, contact holes 132 for exposing the surface of the source/drain region 122 and upper surfaces of the gate electrodes 114 of the transistors 120 are formed in the lower dielectric layer 130 using a photolithographic etching process.

Then, a first barrier metal film 400 is formed along steps of side surfaces and bottom surfaces of the contact holes 132 and on an upper surface of the lower dielectric layer 130. The first barrier metal film 400 can comprise, for example, a titanium film, a titanium nitride film or a composite film comprising a titanium film and a titanium nitride film deposited on the titanium film.

Next, as shown in FIG. 2B, a lower metal layer 138 is formed by depositing titanium or tungsten on the first barrier metal film 400 to fill the contact holes 132. A chemical vapor deposition (CVD) method or a sputtering method is used in the deposition of titanium or tungsten. The lower contact 140 (FIG. 2C) can comprise copper. Since copper is easily diffused into the silicon substrate 100 formed under the lower contact 140, titanium or tungsten can be used to prevent the diffusion of copper according to an embodiment of the present invention.

Next, as shown in FIG. 2C, the lower metal layer 138 and the first barrier metal film 400 comprising titanium or tungsten are polished using the CVD method until a surface of the lower dielectric layer 130 is exposed, thereby forming the lower contacts 140 for filling the contact holes 132. The first barrier metal film 400 remains on sidewalls and bottom surfaces of the lower contacts 140 as the first barrier metal layer 401.

Sequentially, the first etch stop layer 150 is formed on the lower dielectric layer 130 which includes the lower contact 140. The first etch stop layer 150 prevents copper from diffusing in a subsequent thermal process and functions as an etch stopper in a subsequent etching process. Since the transistors 120 sensitive to the diffusion of copper are formed under the first etch stop layer 150, it is preferable that the first etch stop layer 150 is used. The first etch stop layer 150 can comprise a material having a large etch selectivity with respect to the lower dielectric layer 130, for example, SiC or a SiN based material.

A light characteristic of the first etch stop layer 150 is different from those of the lower dielectric layer 130 and the first interlayer dielectric layer 160 formed under and above the first etch stop layer 150, respectively. Thus, when external light is incident, scattering and irregular reflection of the light occur. Therefore, it is necessary to remove a portion of the first etch stop layer 150 existing on the upper portion of the photodiode 110 so that the incident light reaches the photo diode 110.

Sequentially, the first interlayer dielectric layer 160 is formed on the first etch stop layer 150. The first interlayer dielectric layer 160 can comprise a transparent material such as silicon oxide. Alternatively, since a portion of the first interlayer dielectric layer 160 existing on the upper portion of the photo diode 110 can be removed afterward, the first interlayer dielectric layer 160 may comprise an opaque material.

Next, as shown in FIG. 2D, the first interlayer dielectric layer 160 and the first etch stop layer 150 are partially removed using the photolithographic etching process, thereby forming first trenches 162 exposing the lower contacts 140.

Sequentially, the second barrier metal layer 410 is formed along side and bottom surfaces of the first trenches 162 and on an upper surface of the first interlayer dielectric layer 160. The second barrier metal layer 410 is formed to prevent copper from diffusing into the lower dielectric layer 130 and the first interlayer dielectric layer 160 in a subsequent copper deposition process. The second barrier metal layer 410 can comprise, for example, a tantalum layer, a tantalum nitride layer, or a composite layer comprising a tantalum layer and a tantalum nitride layer deposited on the tantalum layer.

Sequentially, copper is deposited on the second barrier metal layer 410 to fill the first trenches 162, thereby forming a second copper layer 159. The second copper layer 159 is formed by depositing copper seed using a sputtering method and performing electrolytic plating.

Next, as shown in FIG. 2E, the second copper layer 159 (shown in FIG. 2D) and the second barrier metal layer 410 disposed on the upper surface of the first interlayer dielectric layer 160 are polished using a CVD method to expose the upper surface of the first interlayer dielectric layer 160. As a result, the lower copper interconnection 170, which is electrically connected to the lower contact 140 and is a conductive line comprising copper, is formed within the first trenches 162. The second barrier metal layer 410 prevents a metal comprising the lower copper interconnection 170 from diffusing into the first interlayer dielectric layer 160.

Next, as shown in FIG. 2F, after the second etch stop layer 180 is formed on a resultant structure and the second interlayer dielectric layer 190 is formed on the second etch stop layer 180, the first interconnection 200 is formed using a method similar to the method of forming the lower copper interconnection 170. The first interconnection 200 includes the fist copper contacts 200a and the first copper interconnects 200b. The first interconnection 200 is fabricated using a dual damascene process for simultaneously forming the first copper contacts 200a and the first copper interconnects 200b. The dual damascene process is a method for simultaneously forming interconnects and vias by performing electrolytic plating once.

The lower copper interconnection 170 is fabricated using a single damascene process which forms a barrier metal layer and a seed layer and then carries out electrolytic plating on the barrier metal layer and the seed layer, thereby forming one copper interconnect. The single damascene process and the dual damascene process are known techniques.

As shown in FIG. 2G, after the third etch stop layer 210 is formed on a resultant structure and then the upper interlayer dielectric layer 220 is formed on the third etch stop layer 210, the second interconnection 230 including the second copper contacts 230a and the second copper interconnects 230b is formed using the dual damascene process. The dual damascene process is used for forming the first interconnection 200. As a result, a multi-layered interconnection structure is obtained.

According to an embodiment of the present invention, a copper interconnection electrically connected to the source/drain region of the transistor 120 can be formed into a multi-layered interconnect.

Although a copper interconnection of a three-layered structure is described in an embodiment of the present invention, the copper interconnection is not limited to the three-layered structure. Alternatively, the copper interconnection of a single, double, or more than three layered structure can be formed.

As shown in FIG. 2H, the protection layer 270 is formed on the upper interlayer dielectric layer 220 including the second interconnection 230. The protection layer 270 can comprise silicon oxide, silicon nitride or silicon carbide. The protection layer 270 is formed on the multi-layered interconnects.

As shown in FIG. 2I, a photoresist is deposited on an upper portion of the protection layer 270 and patterned, thereby forming a first photoresist pattern PR1 partially exposing a first width W1 of upper surface of the protection layer 270 on the upper portion of the photodiode 110. Sequentially, the protection layer 270, the upper interlayer dielectric layer 220, the second and first interlayer dielectric layers 190 and 160, and the third to first etch stop layers 210, 180 and 150 are etched using the first photoresist pattern PR1 as an etch mask. The etching is performed until the lower dielectric layer 130 is exposed. Thus, portions of the interlayer dielectric layers 160, 190 and 220 and the etch stop layers 150, 180 and 210 disposed on the upper portion of the photo diode 110 are removed, thereby forming the cavity 300. Then, the first photoresist pattern PR1 is removed.

As shown in FIG. 2J, resin having transmittance with respect to light so light may be detected by the image device, for example, a spin-on-glass solution, is coated using a spin-on method so that the spin-on dielectric layer 310 of a transparent material is formed with enough thickness to fill the cavity 300.

As shown in FIG. 2K, photoresist is deposited on an upper portion of the spin-on dielectric layer 310 and patterned. As a result, a second photoresist pattern PR2 is formed. A second width W2 of the upper surface of the spin-on dielectric layer 310 on the upper portion of the photo diode 110 is covered by the second photoresist pattern PR2. A portion other than the covered portion is open so that it is etched. Sequentially, the spin-on dielectric layer 310 is etched using the second photoresist pattern PR2 as an etch mask. It is preferable that the second width W2 is slightly wider than the first width W1 of FIG. 2I. Alternatively, the second width W2 may be the same as the first width W1.

As shown in FIG. 2L, the upper portion of the spin-on dielectric layer 310 protruded from the upper portion of the protection layer 270 is formed to have a profile of a lens using an etch-back process or a thermal process.

If an etching time is adjusted based on a principle that a weak edge portion of the spin-on dielectric layer 310 is etched earlier than other portions in performing the etch-back process, the upper portion of the spin-on dielectric layer 310 can be formed in a dome shape. Heat is applied on the upper portion of the spin-on dielectric layer 310 in the thermal process so that the upper portion of the spin-on dielectric layer 310 can be formed in a dome shape by reflowing the spin-on dielectric layer 310.

Accordingly, the upper portion of the spin-on dielectric layer 310 has a structure of a convex lens, i.e., the first micro lens 310a, is formed on its upper portion so that scattering and irregular reflection of the light can be prevented by focusing light on the surface of the photodiode 110.

A curvature of the first micro lens 310a can be changed to adjust the angle of refraction of the first micro lens 310a based on a refractive index of the spin-on dielectric layer 310 comprising a transparent material and the depth of the cavity 300.

As shown in FIG. 2M, the color filter 500 is formed to cover the upper portions of the first micro lens 310a and the protection layer 270. The color filter 500 has array structures of blue, green and red color filters. In an embodiment of the present invention, a single photodiode 110 is shown as a light receiving element. Therefore, one of the blue, green and red color filters is formed.

After forming the first micro lens 310a, the color filter 500 is formed in an embodiment of the present invention. Alternatively, before forming the color filter 500, a material comprising the protection layer 270 is coated and planarized and then the color filter 500 may be formed.

Referring back to FIG. 1, the second micro lens 600 is formed on the color filter 500, thereby completing the image device, i.e., a CMOS image sensor. The second micro lens 600 has a convex lens shape.

The second micro lens 600 can further improve performance of the first micro lens 310a. If light is focused sufficiently by only the first micro lens 310a, forming the second micro lens 600 can be omitted.

According to an embodiment of the present invention, since the multi-layered interconnects connected to the transistors are made of copper, problems such as low-speed and high resistance can be minimized. Further, portions of the etch stop layers and the interlayer dielectric layers disposed on the upper portion of the photodiode 110 are removed in the damascene process for forming the copper interconnects. A transparent material such as resin is deposited in the cavity left by the removed portions so that the CMOS image sensor with improved light transmittance can be formed. Further, the upper portion of the resin is formed into a convex lens shape so that scattering and irregular reflection of the light can be prevented by focusing light on the surface of the photodiode 110.

Accordingly, a fabrication process of the image device can be simplified by simultaneously forming the micro lens for improving light sensitivity when forming the spin-on dielectric layer deposited for improving light transmittance.

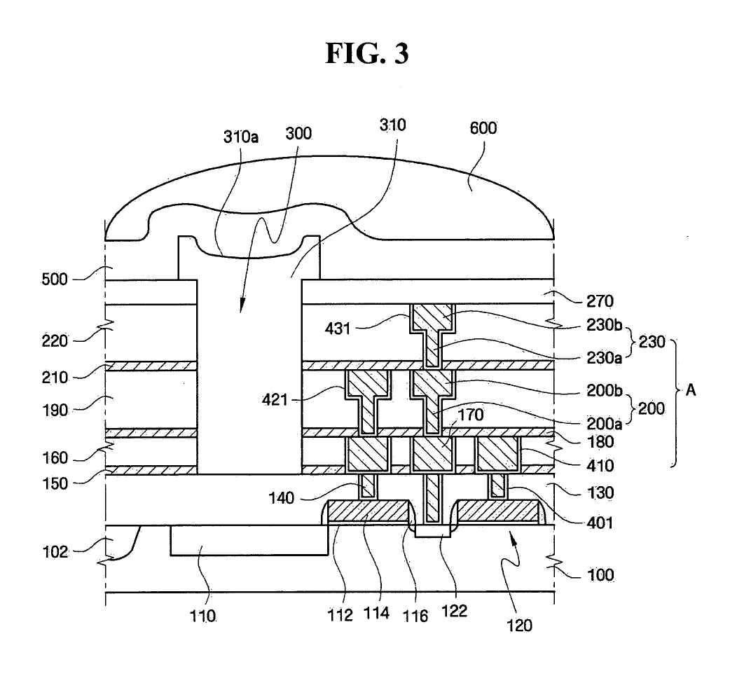

An image device according to an embodiment of the present invention will be described with reference to FIG. 3. FIG. 3 is a cross-sectional view of an image device according to an embodiment of the present invention.

As shown in FIG. 3, the image device according to an embodiment of the present invention has substantially the same structure as the image device shown in FIG. 1, except for an upper structure of a spin-on dielectric layer 310 comprising a transparent material that fills the cavity 300 formed in an interlayer dielectric structure A.

The transparent material filling the cavity 300 may be resin that is transmissible with respect to light detected by the image device. The spin-on dielectric layer 310 completely fills the cavity 300 and its upper portion has a profile of a concave lens. The spin-on dielectric layer 310 has the first micro lens 310a having a profile of a concave lens. The first micro lens 310a enables light to be uniformly received on the surface of the photodiode 10, thereby preventing irregular reflection of the light.

A color filter 500 is formed on the spin-on dielectric layer 310 and a protection layer 270 in the image device according to an embodiment of the present invention. A second micro lens 600 having a convex lens shape is formed on top of the color filter 500. The second micro lens 600 focuses light on the surface of the photodiode 110.

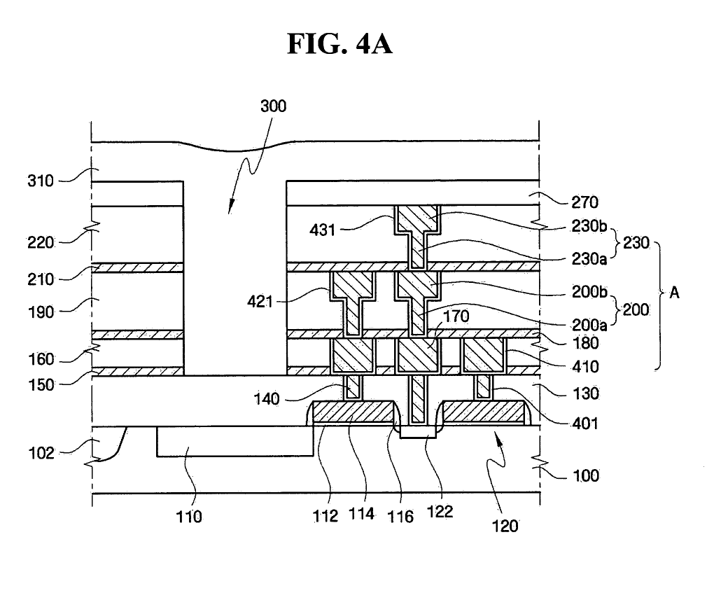

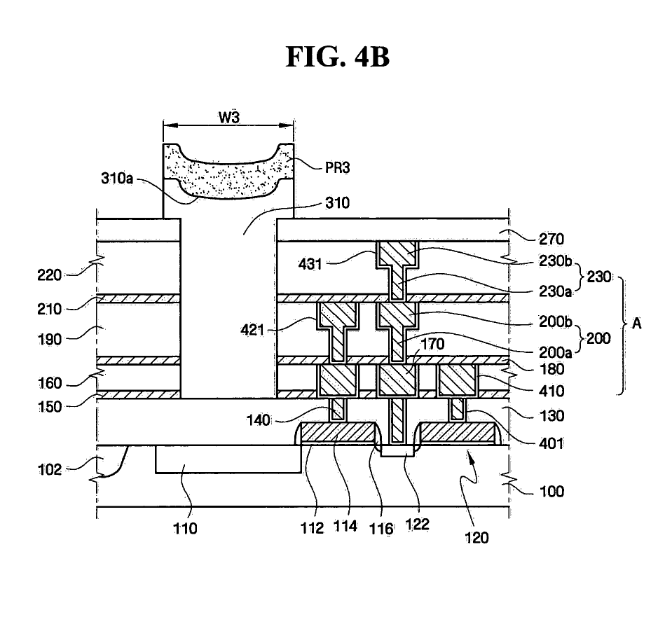

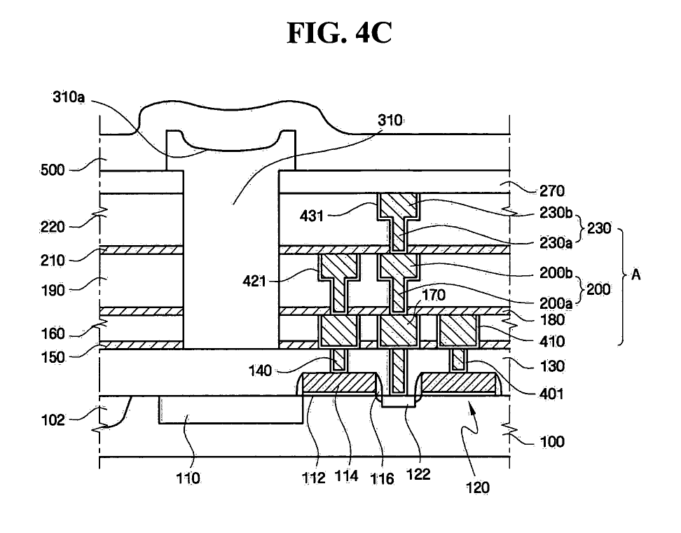

A method of fabricating the image device according to an embodiment of the present invention will be described with reference to FIGS. 4A through 4C and FIG. 3.

FIGS. 4A through 4C are cross-sectional views illustrating a method of fabricating an image device shown in FIG. 3 according to an embodiment of the present invention. The processes performed until forming the cavity 300 in the interlayer dielectric structure A in the embodiment shown in FIG. 3 are the same as the processes performed until forming the cavity 300 in the embodiment shown in FIG. 1, and a detailed explanation thereof will not be given.

As shown in FIG. 4A, a spin-on-glass solution is coated by a spin-on method so that the spin-on dielectric layer 310 comprising a transparent material is formed using an appropriate amount of the spin-on-glass solution, thereby filling the cavity 300. A recessed structure of the cavity 300 creates a concave portion on the coating surface of the spin-on dielectric layer 310. Therefore, when the spin-on-glass solution is coated by the spin-on method, it is preferable that an appropriate amount of the spin-on-glass solution is coated to form a surface of the spin-on dielectric layer 310 into a concave lens shape.

As shown in FIG. 4B, a photoresist is deposited on an upper portion of the spin-on dielectric layer 310 and patterned, thereby forming a third photoresist pattern PR3. The third photoresist pattern PR3 having a third width W3 covers an upper surface of the spin-on dielectric layer 310 on an upper portion of a photo diode 110. A portion other than the covered portion is open so that it is etched. Then, the spin-on dielectric layer 310 is etched using the third photoresist pattern PR3 as an etch mask. The third width W3 may be slightly wider than the width of the cavity 300. Alternatively, the third width W3 may be the same as the width of the cavity 300. Then, the third photoresist pattern PR3 is removed.

Accordingly, a first micro lens 310a having a profile of a concave lens is formed. Scattered reflection of the light can be prevented by uniformly receiving light on the surface of the photodiode 110 from the first micro lens 310a having the concave lens shape. A curvature of the first micro lens 310a can be changed to adjust a refractive index of the spin-on dielectric layer 310 comprising a transparent material. The depth of the cavity 300 can be changed to adjust the angle of refraction of the first micro lens 310a.

As shown in FIG. 4C, a color filter 500 is formed to cover the upper portions of the first micro lens 310a and the protection layer 270. The color filter 500 has array structures of blue, green and red color filters. In an embodiment of the present invention, since a single photodiode 110 is shown as a light receiving element, one of the blue, green and red color filters is formed.

Before forming the color filter 500, the protection layer 270 can be coated and planarized.

Referring back to FIG. 3, the second micro lens 600 for focusing light on the photodiode 110 is formed on the color filter 500, thereby completing an image device, i.e., a CMOS image sensor. The second micro lens 600 has a convex lens shape.

The second micro lens 600 focuses light on the surface of the photodiode 110. An irregular reflection of light reflected at a sidewall of the cavity 300 may occur when the focused light is unduly concentrated. The first micro lens 310a of the concave lens type enables the light to be uniformly received to the photodiode 110, thereby preventing scattering and irregular reflection of the light.

According to an embodiment of the present invention, since multi-layered interconnects connected to transistors comprise copper having low resistance, low-speed or high resistance problems can be avoided. Portions of etch stop layers used in a damascene process for forming the copper interconnects and interlayer dielectric layers disposed on the upper portion of the photodiode 10 are removed. A transparent material such as resin is deposited in the cavity 300 left by the removed portions. As a result, the CMOS image sensor with improved light transmittance can be formed. In addition, the upper portion of the transparent material is formed as a concave lens shape to cause the focused light to be uniformly received to the photodiode 10, thereby preventing scattering and irregular reflection of the light.

Accordingly, forming a micro lens for improvement of light sensitivity and forming a dielectric layer comprising a transparent material for improvement of light transmittance are simultaneously performed, thereby simplifying a fabrication process of the image device.

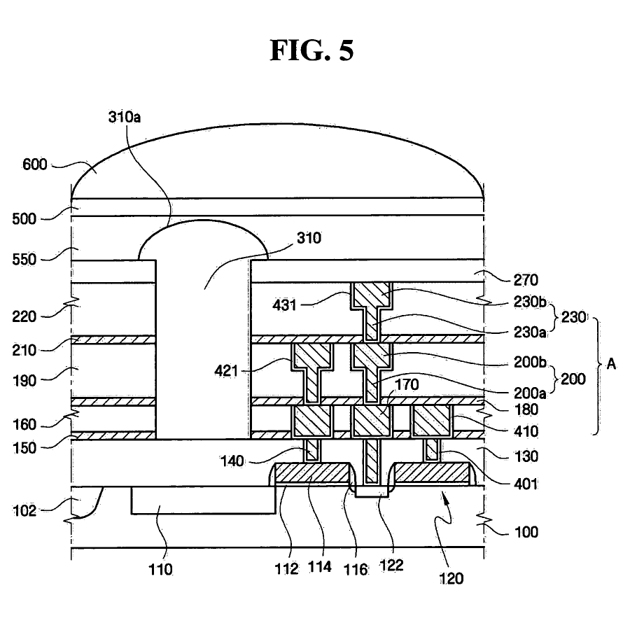

An image device according to an embodiment of the present invention will be described with reference to FIG. 5.

FIG. 5 is a cross-sectional view of an image device according to an embodiment of the present invention. As shown in FIG. 5, the image device according to an embodiment of the present invention has substantially the same structure as the image device shown in FIG. 1, except for structures of a protection layer 550 formed on an upper portion of a first micro lens 310a, a color filter 500, and a second micro lens 600 formed thereon.

The image device according to an embodiment of the present invention further includes a second protection layer 550 which is evenly formed on the upper portion of the first micro lens 310a having a convex lens shape. The second protection layer 550 comprises a transparent material.

The color filter 500 is evenly formed on an upper portion of the second protection layer 550. The second micro lens 600 of a convex lens type is formed on an upper portion of the color filter 500.

Although preferred embodiments have been described herein with reference to the accompanying drawings, it is to be understood that the present invention is not limited to those precise embodiments, and that various other changes and modifications may be affected therein by one of ordinary skill in the related art without departing from the scope or spirit of the invention.

What is claimed is:

1. An image device comprising:
a substrate including a light receiving element formed therein;
an interlayer dielectric structure formed on the substrate and having a cavity formed over the light receiving element;
a transparent dielectric layer, wherein the transparent dielectric layer fills the cavity and including a lens-shaped portion protruding beyond an upper portion of the interlayer dielectric structure; and
a color filter which is formed on the transparent dielectric layer.

2. The image device of claim 1, further comprising a micro lens formed on the color filter.

3. The image device of claim 2, further comprising a protection layer planarly formed between the transparent dielectric layer and the color filter.

4. The image device of claim 1, wherein an upper portion of the transparent dielectric layer is a convex lens shape.

5. The image device of claim 1, wherein an upper portion of the transparent dielectric layer is a concave lens shape.

6. The image device of claim 1, wherein the interlayer dielectric structure includes etch stop layers and interlayer dielectric layers, wherein copper contacts and copper interconnects are formed.

7. The image device of claim 1, wherein the transparent dielectric layer comprises a spin-on-dielectric material.

8. An image device comprising:
a substrate including a light receiving element formed therein;
a semiconductor device for driving the light receiving element;
an interlayer dielectric structure formed on the substrate, the interlayer dielectric structure including etch stop layers and interlayer dielectric layers, wherein copper contacts electrically connected to the semiconductor device and copper interconnects are formed, and the interlayer dielectric structure having a cavity formed by removing respective portions of the etch stop layers and interlayer dielectric layers formed over the light receiving element;
a transparent dielectric layer, wherein the transparent dielectric layer fills the cavity and includes a convex lens-shaped portion protruding beyond an upper portion of the interlayer dielectric structure; and
a color filter formed on the transparent dielectric layer.

9. The image device of claim 8, further comprising a micro lens formed on the color filter.

10. The image device of claim 8, wherein the transparent dielectric layer comprises a spin-on-dielectric material.

11. An image device comprising:
a substrate including a light receiving element formed therein;
a semiconductor device for driving the light receiving element;
an interlayer dielectric structure formed on the substrate, the interlayer dielectric structure including etch stop layers and interlayer dielectric layers, wherein copper contacts electrically connected to the semiconductor device and a copper interconnects are formed, and the interlayer dielectric structure having a cavity formed by removing the etch stop layers and interlayer dielectric layers formed over the light receiving element;
a transparent dielectric layer, wherein the transparent dielectric layer fills the cavity and includes a concave lens-shaped portion protruding beyond an upper portion of the interlayer dielectric structure;
a color filter formed on the transparent dielectric layer; and
a convex micro lens formed on the color filter.

12. The image device of claim 11, wherein the transparent dielectric layer comprises a spin-on-dielectric material.

13. A method of fabricating an image device comprising:
forming a semiconductor device for driving a light receiving element, and forming an interlayer dielectric structure including copper contacts electrically connected to the semiconductor device and copper interconnects, on a substrate including the light receiving element formed therein;
removing a portion of the interlayer dielectric structure disposed on over upper portion of the light receiving element to form a cavity;
forming a transparent dielectric layer having a thickness to fill the cavity;
forming an upper portion of the transparent dielectric layer over the light receiving element to form a first micro lens; and
forming a color filter on the first micro lens.

14. The method of claim 13, further comprising forming a second micro lens on the color filter.

15. The method of claim 13, further comprising before forming the color filter, forming a protection layer on the first micro lens and planarizing the protection layer.

16. The method of claim 13, wherein forming the first micro lens comprises:
planarizing the transparent dielectric layer;
removing the transparent dielectric layer except for a portion of the transparent dielectric layer disposed over the light receiving element; and
performing an etch-back process to form the upper portion of the transparent dielectric layer disposed over the light receiving element into a convex lens shape.

17. The method of claim 16, wherein the etch-back process is performed until an edge portion of the upper portion of the transparent dielectric layer is removed until the upper portion of the transparent dielectric layer is formed into the convex lens shape.

18. The method of claim 13, wherein forming the first micro lens comprises:
planarizing the transparent dielectric layer;
removing the transparent dielectric layer except for the transparent dielectric layer disposed over the light receiving element; and
performing a thermal process to reflow the upper portion of the transparent dielectric layer disposed over the light receiving element, thereby forming the upper portion of the transparent dielectric layer into a concave lens type.

19. The method of claim 13, wherein the copper contacts and the copper interconnects are formed within etch stop layers and interlayer dielectric layers using a damascene process, and the cavity is formed by removing respective portions of the etch stop layers and the interlayer dielectric layers on the light receiving element using a photolithographic etching process.

20. A method of fabricating an image device comprising:
forming a semiconductor device for driving a light receiving element, and forming an interlayer dielectric structure including copper contacts electrically connected to the semiconductor device and copper interconnects, on a substrate including the light receiving element formed therein;
removing a portion of the interlayer dielectric structure disposed over the light receiving element to form a cavity;
forming a transparent dielectric layer having a thickness to fill the cavity, the transparent dielectric layer being formed to a predetermined thickness such that an upper portion of the cavity has a concave profile;
removing the transparent dielectric layer except for the transparent dielectric layer disposed over the light receiving element to form a first micro lens wherein the upper portion of the transparent dielectric layer is formed into a concave lens shape;
forming a color filter on the first micro lens; and
forming a second micro lens on the color filter.

21. The method of claim 20, wherein the second micro lens is a convex micro lens.

22. The method of claim 21, further comprising, before forming the color filter, forming a protection layer on the interlayer dielectric structure and planarizing the protection layer.

23. The method of claim 20, wherein the copper contacts and the copper interconnects are formed within etch stop layers and interlayer dielectric layers using a damascene process, and the cavity is formed by removing the etch stop layers and the interlayer dielectric layers over the light receiving element using a photolithographic etching process.
